(19) United States
(12) Patent Application Publication
(10) Pub. No.: US 2015/0035061 A1
(43) Pub. Date: Feb. 5, 2015

(54) Semiconductor Device and Method for Fabricating the Same

(71) Applicant: Samsung Electronics Co., Ltd., Suwon-si (KR)

(72) Inventors: Chang-Seop Yoon, Yangsan-si (KR); Hee-Soo Kang, Seoul (KR); Jong-Wook Lee, Yongin-si (KR); Soon Cho, Hwaseong-si (KR)

(73) Assignee: Samsung Electronics Co., Ltd., Suwon-si (KR)

(21) Appl. No.: 14/262,230

(22) Filed: Apr. 25, 2014

(30) Foreign Application Priority Data
Jul. 31, 2013 (KR) 10-2013-0090901

(51) Int. Cl. H01L 29/66; H01L 29/78

(52) U.S. Cl. CPC H01L 29/6681; H01L 29/7855
USPC 257/365; 438/283

(57) ABSTRACT

Provided are a multi-gate transistor device and a method for fabricating the same. The method for fabricating the multi-gate transistor device includes forming first and second fins shaped to protrude on a substrate and aligned and extending in a first direction and a trench separating the first and second fins from each other in the first direction between the first and second fins, performing ion implantation of impurities on sidewalls of the trench, forming a field dielectric film filling the trench, forming a recess in the first fin not exposing the field dielectric film, and growing an epitaxial layer in the recess.

### CROSS-REFERENCE TO RELATED APPLICATION

This application claims priority from Korean Patent Application No. 10-2013-0090901 filed on Jul. 31, 2013 in the Korean Intellectual Property Office, and all the benefits accruing therefrom under 35 U.S.C. 119, the disclosure of which is incorporated by reference herein in its entirety.

### FIELD

The present inventive concept relates to a semiconductor device and a method for fabricating the same.

### BACKGROUND

Scaling techniques may increase the density of integrated circuit devices. Some scaling techniques involve a multi-gate transistor, in which a fin- or nanowire-shaped multi-channel active pattern (or a silicon body) is formed on a substrate and a gate is then formed on a surface of the multi-channel active pattern.

### SUMMARY

Embodiments of the present inventive concept provide semiconductor devices having improved operating characteristics by preventing a short and epitaxially growing a source/drain without abnormality.

Embodiments of the present inventive concept also provide methods for fabricating a multi-gate transistor device having improved operating characteristics by preventing a short and epitaxially growing a source/drain without abnormality.

According to some embodiments of the present inventive concept, a method for fabricating a multi-gate transistor device includes forming first and second fins shaped of the multi-gate transistor device to protrude on a substrate and aligned and extending in a first direction and a trench separating the first and second fins from each other in the first direction between the first and second fins, performing an angled ion implantation of impurities on sidewalls of the trench, forming a field dielectric film filling the trench, forming a recess in the first fin, not exposing the field dielectric film, and growing an epitaxial layer in the recess.

According to other embodiments of the present inventive concept, a multi-gate transistor device includes first and second fins shaped to protrude on a first region of a substrate, aligned and extending in a first direction and spaced apart from each other in the first direction, a first field dielectric film formed between the first and second fins, a first dummy gate structure extending on the first field dielectric film in a second direction and a first normal gate structure extending on the first fin in the second direction, and a first source/drain formed between the first normal gate structure and the first dummy gate structure. The first fin may include a third region disposed between the first source/drain and the first field dielectric film and doped with impurities.

According to some embodiments, a method for fabricating a multi-gate transistor device may include etching an active region formed on a substrate down to the substrate using a first mask extending in a first direction to form a fin shape, etching the fin shape down to the substrate to form a trench between a first fin and a second fin aligned with the first fin in the first direction, performing ion implantation of impurities into the trench at angles not perpendicular to the substrate using the first mask such that impurities are implanted into sidewalls of the first and second fins exposed to the trench and not into the substrate exposed at a bottom of the trench, forming a field dielectric film to fill the trench, forming a recess in the first fin not exposing the field dielectric film, growing a source/drain epitaxial layer in the recess and forming a gate on the first fin and a dummy gate on the field dielectric film.

### BRIEF DESCRIPTION OF THE DRAWINGS

The above and other features and advantages of the present inventive concept will become more apparent by describing in detail preferred embodiments thereof with reference to the attached drawings in which:

FIGS. 1 to 16 illustrate intermediate process steps of a method for fabricating a semiconductor device according to an embodiment of the present inventive concept;

FIGS. 17 to 20 illustrate intermediate process steps of a method for fabricating a semiconductor device according to another embodiment of the present inventive concept;

FIGS. 21 to 24 illustrate intermediate process steps of a method for fabricating a semiconductor device according to still another embodiment of the present inventive concept;

FIG. 25 is a cross-sectional view of a semiconductor device according to still another embodiment of the present inventive concept;

FIGS. 26 and 27 are a circuit view and a layout view of a semiconductor device according to still another embodiment of the present inventive concept; and

FIG. 28 is a block diagram of an electronic system including semiconductor devices 1 to 3 according to some embodiments of the present inventive concept.

FIGS. 29 and 30 illustrate an exemplary semiconductor system to which semiconductor devices according to some embodiments of the present inventive concept can be employed.

### DETAILED DESCRIPTION

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Since the multi-gate transistor uses a three-dimensional (3D) channel, scaling of the multi-gate transistor may be more easily achieved. In addition, current controlling capability can be improved without increasing a gate length of the multi-gate transistor. Further, a short channel effect (SCE), in which an electric potential of a channel region is affected by a drain voltage, can be effectively suppressed.

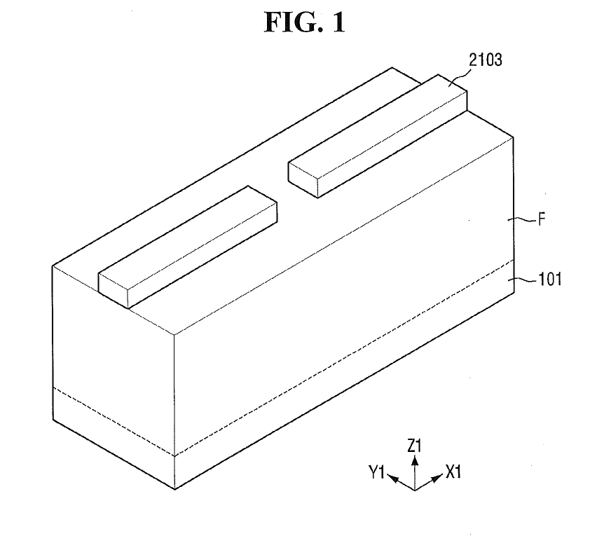

Hereinafter, a semiconductor device according to an embodiment of the present inventive concept will be described with reference to FIGS. 1 to 16.

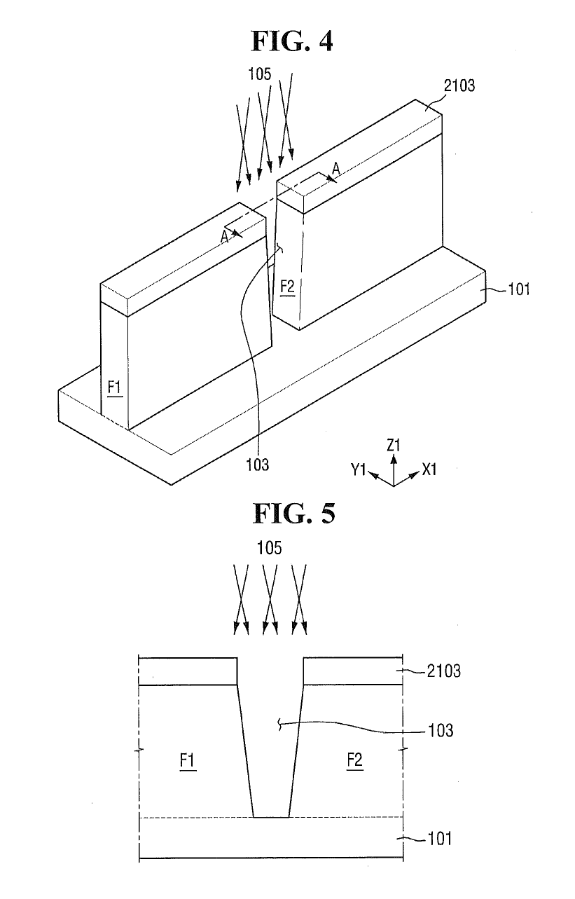

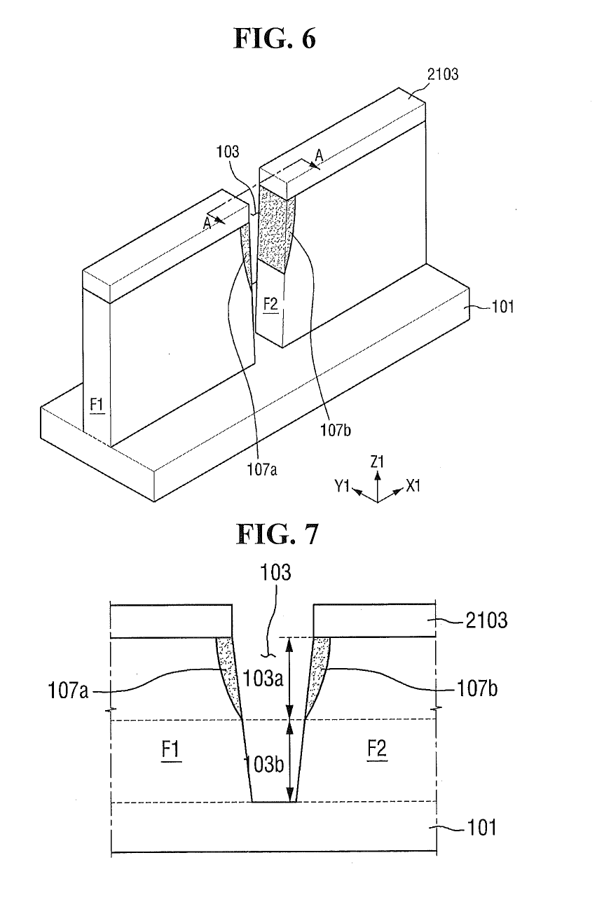

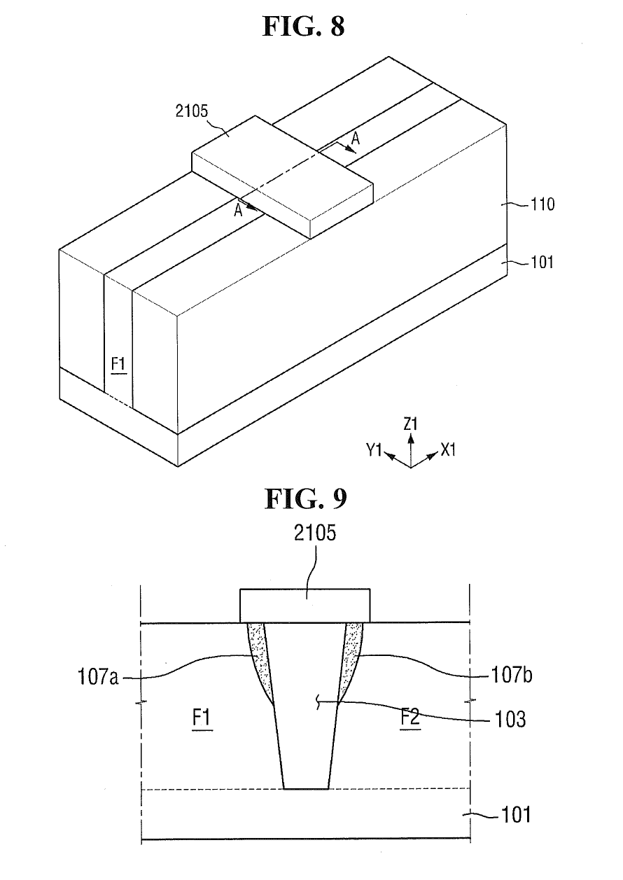

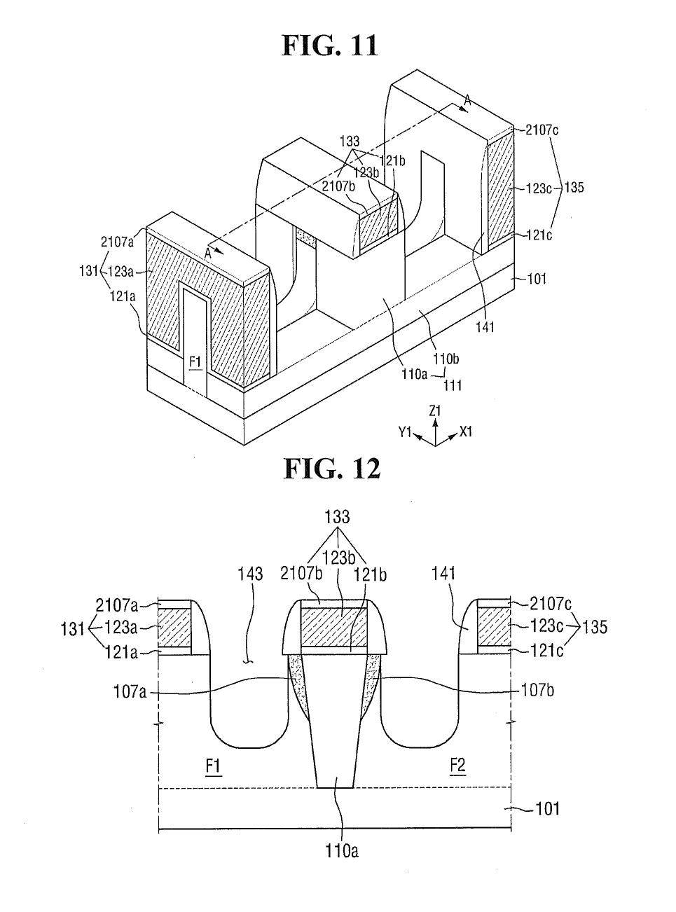

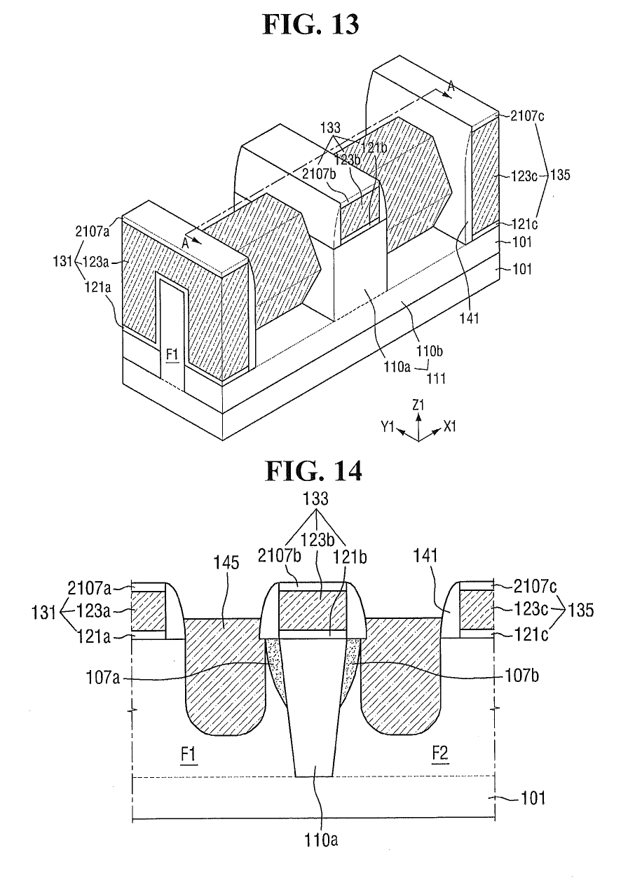

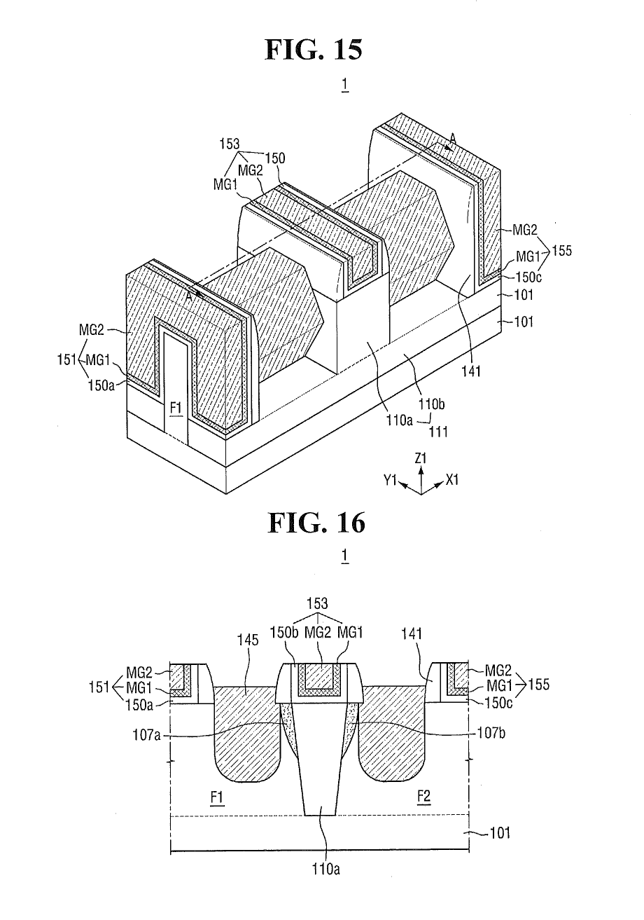

FIGS. 1 to 16 illustrate intermediate process steps of a method for fabricating a semiconductor device according to an embodiment of the present inventive concept. In detail, FIGS. 1, 2, 4, 6, 8, 10, 11, 13 and 15 are perspective views of a semiconductor device according to an embodiment of the present inventive concept. FIG. 3 is a cross-sectional view taken along the line A-A of FIG, 2. FIG. 5 is a cross-sectional view taken along the line A-A of FIG. 4. FIG. 7 is a cross-sectional view taken along the line A-A of FIG. 6. FIG. 9 is a cross-sectional view taken along the line A-A of FIG. 8. FIG. 12 is a cross-sectional view taken along the line A-A of FIG. 11. FIG. 14 is a cross-sectional view taken along the line A-A of FIG. 13. FIG. 16 is a cross-sectional view taken along the line A-A of FIG. 15.

First, referring to FIG. 1, an active region F is formed on a substrate 101 and a first mask 2103 is formed on the active region F. The first mask 2103 is formed at portions where first and second fins (F1 and F2 of FIG. 3) to be formed later are disposed.

The substrate 101 may be made of one or more semiconductor materials selected from the group consisting of, for example, Si, Ge, SiGe, GaP, GaAs, SiC, SiGeC, InAs and InP. Alternatively, the substrate 101 may be a silicon on insulator (SOI) substrate.

The active region F may be integrally formed with the substrate 101 and may include the same material with the substrate 101.

The first mask 2103 may be formed of at least one of a silicon oxide film, a silicon nitride film and a silicon oxynitride film.

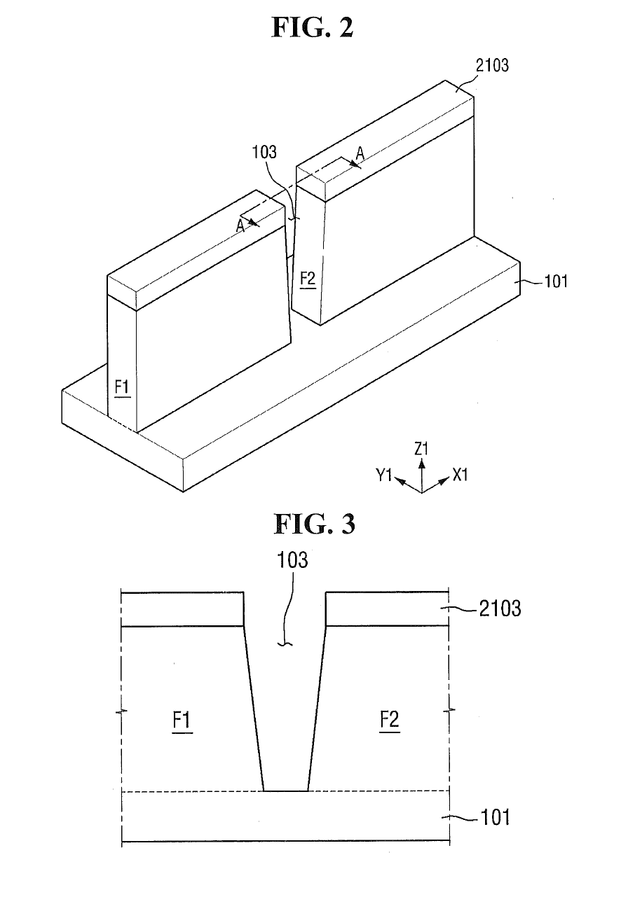

Next, referring to FIGS. 2 and 3, an etching process is performed using a first mask 2103 as a mask. As the result of the etching process, a first fin F1, a second fin F2 and a trench 103 are formed. The first and second fins F1 and F2 may be formed to protrude on the substrate 101 in a third direction (in a Z1 direction). In addition, the first and second fins F1 and F2 may extend lengthwise in a first direction (in an X1 direction).

In the illustrated embodiment, the first and second fins F1 to F2 are shaped substantially as rectangles, but embodiments of the present inventive concept are not limited thereto. For example, the first and second fins F1 to F2 may be chamfered. That is, corner portions may be rounded. Since the first and second fins F1 to F2 are formed lengthwise in the first direction X1, they may include long sides formed along the first direction X1 and short sides formed along a second direction Y1. Even if the corners of the first and second fins F1 to F2 are rounded, it is obvious to one skilled in the art that the long sides can be distinguished from the short sides.

The trench 103 is formed between the first and second fins F1 and F2. The trench 103 separates the first and second fins F1 and F2 from each other in the first direction X1. Both sidewalls of the trench 103 may correspond to sidewalls of the first and second fins F1 and F2. In addition, a width of the trench 103 may gradually increase from a lower portion to a top portion of the trench, but aspects of the present inventive concept are not limited thereto. For example, the trench 103 may be constant in width in a longitudinal direction from its lower portion to its top portion.

Next, referring to FIGS. 4 and 5, ion implantation 105 is performed to inject impurities into sidewalls of the trench 103. The ion implantation 105 is performed while not removing the first mask 2103, so that the impurities are not injected into top surfaces of the first and second fins F1 and F2. Since the ion implantation 105 is performed using the first mask 2103 used to form the first and second fins F1 and F2, additional process or cost may not be required to perform the ion implantation 105.

The ion implantation 105 may be angled ion implantation. In the ion implantation 105, impurities may not be injected in the third direction (i.e., in the Z1 direction) perpendicular to the substrate 101. For example, the ion implantation 105 may be performed on a plane of the third direction (i.e., the Z1 direction) at an acute angle or an obtuse angle with respect to the first direction (i.e., the X1 direction). FIGS. 6 and 7 illustrate resultant products after the performing of the ion implantation 105. Since the angled ion implantation 105 is performed, the impurities are injected into the sidewalls of the trench 103 while not being injected into the bottom surface of the trench 103. In detail, the sidewalls of the trench 103 may include a first region 103a and a second region 103b. The second region 103b may be positioned to be closer to the substrate 101 than the first region 103a, and the first region 103a may be brought into contact with the first mask 2103. Through the ion implantation 105, the impurities are not injected into second region 103b but are injected into only the first region 103a. This does not exclude the possibility that, in some cases, a small amount of impurities may incidentally enter second region 103b, but not enough to substantially reduce the performance of the device,

The impurities may be injected only into targeted portions through the angled ion implantation 105. Since the impurities may not be injected into portions other than the third regions 107a and 107b, or sidewall pocket implant regions, of the first and second fins F1 and F2, it is possible to prevent unexpected results, such as a short or a reduction in the performance of device, from occurring.

Since the third regions 107a and 107b of the first and second fins F1 and F2 are formed to make contact with the first region 103a on the sidewalls of the trench 103, they may be spaced apart from the substrate 101 in the third direction (i.e., in the Z1 direction).

The sizes, thicknesses and heights of the third regions 107a and 107b of the first and second fins F1 and F2 may vary according to the angle or intensity of the angled ion implantation 105 and the amount of doped impurities.

The impurities may prevent the third regions 107a and 107b from being etched when a recess (143 of FIG. 12) is formed in the first and second fins F1 and F2 and may include, for example, a material capable of reducing an etch rate, such as nitrogen (N) or carbon (C), but aspects of the present inventive concept are not limited thereto.

Referring to FIGS. 8 and 9, the first mask 2103 is removed to form an insulation layer 110. The insulation layer 110 may cover the top surface of the substrate 101 and sidewalls of the first and second fins F1 and F2 while exposing top surfaces of the first and second fins F1 and F2. In addition, the insulation layer 110 fills the trench 103.

Next, a mask layer pattern 2105 is formed on the trench 103. The mask layer pattern 2105 may be formed of at least one of a silicon oxide film, a silicon nitride film and a silicon oxynitride film.

The mask layer pattern 2105 may prevent the insulation layer 110 in the trench 103 from being removed. A width of the mask layer pattern 2105 may be greater than an upper width of the trench 103. In some cases, the mask layer pattern 2105 may completely cover the insulation layer 110 in the trench 103 and may also cover portions of the top surfaces of the first and second fins F1 and F2. The mask layer pattern 2105 may cover top surfaces of the third regions 107a and 107b.

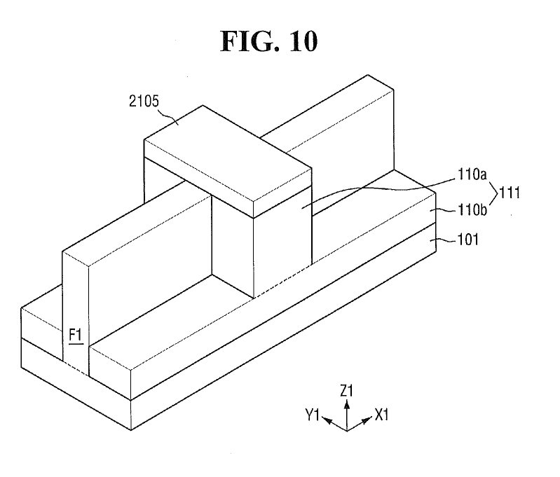

Referring to FIG. 10, the insulation layer 110 is etched using the mask pattern 2105. A field dielectric film 111 may be formed by etching the insulation layer 110. The field dielectric film 111 includes a first field dielectric film 110a formed under the mask pattern 2105 and a second field dielectric film 110b formed on the substrate 101 and covering sidewalls of lower portions of the first and second fins F1 and F2. The first field dielectric film 110a may extend in the second direction (i.e., in the Y1 direction).

Since the impurities are not doped into a lower portion of the trench 103 and the first field dielectric film 110a completely fills the trench 103, heights of the doped third regions 107a and 107b are smaller or less than a height of the first field dielectric film 110a.

Referring to FIGS. 11 and 12, the mask pattern 2105 is removed. After the mask pattern 2105 is removed, a first dummy gate 131 is formed on the first fin F1, a second dummy gate 133 is formed on the first field dielectric film 110a, and a third dummy gate 135 is formed on the second fin F2. The first to third dummy gates 131, 133 and 135 may extend in the second direction (i.e., in the Y1 direction). The first and third dummy gates 131 and 135 intersect the first and second fins F1 and F2, respectively, and may be formed along the sidewalls and top surfaces of the first and second fins F1 and F2. However, since the first field dielectric film 110a extends in the second direction (i.e., in the Y1 direction), the second dummy gate 133 is formed on the first field dielectric film 110a.

The first to third dummy gates 131, 133 and 135 may include first to third dummy gate dielectric films 121a, 121b and 121c, first to third dummy gate electrodes 123a, 123b and 123c and first to third dummy gate mask patterns 2107a, 2107b and 2107c, respectively, which are sequentially formed.

For example, the first to third dummy gate dielectric films 121a, 121b and 121c may be silicon oxide films, and the first to third dummy gate electrodes 123a, 123b and 123c may include polysilicon.

A spacer 141 may be formed on sidewalls of the first to third dummy gate electrodes 123a, 123b and 123c and may expose top surfaces of the first to third dummy gate mask patterns 2107a, 2107b and 2107c. The spacer 141 may be formed of a silicon nitride film or a silicon oxynitride film.

Next, a recess 143 is formed in the first and second fins F1 and F2. That is to say, the recess 143 may be formed in the first and second fins F1 and F2 exposed because the first to third dummy gates 131, 133 and 135 are not formed. The recess 143 may be formed between the first dummy gate 131 and the second dummy gate 133 and between the second dummy gate 133 and the third dummy gate 135.

When the recess 143 is formed, the first field dielectric film 110a is not exposed by the third regions 107a and 107b formed at both sides of the first field dielectric film 110a. Since the third regions 107a and 107b are doped with impurities, they may not be exposed or may be partially exposed. In addition, a bottom surface of the second dummy gate 133 may not be exposed by the third regions 107a and 107b, either. However, the bottom surface of the spacer 141 formed at both sides of the second dummy gate 133 may be partially exposed by forming the recess 143.

Referring to FIGS. 13 and 14, an epitaxial layer 145 is formed in the recess 143. The epitaxial layer 145 may be formed by epitaxial growth. The epitaxial layer 145 may be a source/drain. The epitaxial layer 145 may be an elevated source/drain formed to protrude relative to the first and second fins F1 and F2.

When the epitaxial layer 145 is a source/drain of a PMOS transistor, it may include a compressive stress material. For example, the compressive stress material may include a material having a greater lattice constant than Si (e.g., SiGe). The compressive stress material may improve the mobility of carriers of a channel region by applying compressive stress to the first and second fins F1 and F2.

Meanwhile, when the epitaxial layer 145 is a source/drain of an NMOS transistor, it may include the same material as the substrate 101 or a tensile stress material. For example, when the substrate 101 includes Si, the epitaxial layer 145 may include Si or a material having a smaller lattice constant than Si (e.g., SiC). The tensile stress material may improve the mobility of carriers of a channel region by applying tensile stress to the first and second fins F1 and F2.

The epitaxial layer 145 may be formed on surfaces of the first and second fins F1 and F2 using epitaxial growth. Since the first field dielectric film 110a includes a different material from the first and second fins F1 and F2 (for example, since the first and second fins F1 and F2 may include Si and the first field dielectric film 110a may include SiO₂), the epitaxial layer 145 may not be formed on the surface of the first field dielectric film 110a. However, the third regions 107a and 107b are not doped with impurities, portions of the first and second fins F1 and F2 making contact with the first field dielectric film 110a when the recess 143 is formed may be etched to expose sidewalls of the first field dielectric film 110a. In a case where the first field dielectric film 110a is exposed, the epitaxial layer 145 may not grow on the sidewalls of the first field dielectric film 110a. Therefore, the epitaxial layer 145 may not completely fill the recess 143, so that voids may be generated. If voids are present, performance of a transistor may be lowered. For example, resistance of the epitaxial layer 145 may increase. However, according to embodiments of the present inventive concept, since the third regions 107a and 107b are doped with impurities, the first field dielectric film 110a is not exposed when the recess 143 is formed. Therefore, voids are not generated in the recess 143.

In addition, since the bottom surface of the second dummy gate 133 is not exposed by the third regions 107a and 107b, the bottom surface of the second gate structure 153 (FIGS, 15 and 16) may not make contact with the epitaxial layer 145 even if the second dummy gate 133 is later removed and the second gate structure 153 is formed at a region where the second dummy gate 133 is positioned. Therefore, a short is not generated between the epitaxial layer 145 and the second gate structure 153.

When the recess 143 is formed, a portion of the bottom surface of the spacer 141 may also be exposed. The epitaxial layer 145 formed in the recess 143 may cover the exposed bottom surface of the spacer 141. In such a way, the epitaxial layer 145 is tucked. In detail, the epitaxial layer 145 may be shaped to be tucked into a lower portion of the spacer 141. The epitaxial layer 145 may also be formed at the lower portion of the spacer 141.

Referring to FIGS. 15 and 16, the first to third dummy gates 131, 133 and 135 are removed and first to third gate structures 151, 153 and 155 are formed in place of the removed first to third dummy gates 131, 133 and 135. That is, the first to third gate structures 151, 153 and 155 may replace the first to third dummy gates 131, 133 and 135. Accordingly, the semiconductor device 1 according to an embodiment of the present inventive concept can be fabricated.

The first and third gate structures 151 and 155 may be formed on the first and second fins F1 and F2 to intersect the first and second fins F1 and F2. The first and third gate structures 151 and 155 may extend in the second direction (i.e., in the Y1 direction). The second gate structure 153 may be formed on the first field dielectric film 110a and may extend in the second direction (i.e., in the Y1 direction).

Here, the first and third gate structures 151 and 155 may be normal or active gate structures and the second gate structure 153 formed on the first field dielectric film 110a may be a dummy gate structure. The first and third gate structures 151 and 155 actually serve as gates of transistors while the second gate structure 153 does not serve as a gate of a transistor. However, the second gate structure 153 and the first and third gate structures 151 and 155 have a similar shape and may be formed by substantially the same method.

The first to third gate structures 151, 153 and 155 may include first to third gate dielectric films 150a, 150b and 150c and metal layers MG1 and MG2.

The first to third gate structures 151, 153 and 155 may include metal layers MG1 and MG2. As shown, the first to third gate structures 151, 153 and 155 may include two or more metal layers MG1 and MG2. The first metal layer MG1 may function to adjust a work function, and the second metal layer MG2 may function to fill a space formed by the first metal layer MG1. For example, the first metal layer MG1 may include at least one of TiN, TaN, TiC, and TaC. In addition, the second metal layer MG2 may include W or Al. The metal layers MG1 and MG2 may be formed by, for example, a replacement process, but aspects of the present inventive concept are not limited thereto.

The first to third gate dielectric films 150a, 150b and 150c may be formed between the first fin F1 and the first field dielectric film 110a and between the second fin F2 and each of the metal layers MG1 and MG2, respectively. As shown in FIGS. 15 and 16, the first gate dielectric film 150a may be formed along a top surface and upper portions of lateral surfaces of the first fin F1. The second gate dielectric film 150b may be formed along a top surface of the first field dielectric film 110a. The third gate dielectric film 150c may be formed along a top surface and upper portions of lateral surfaces of the second fin F2. In addition, the first and second gate dielectric films 150a and 150c may be positioned between each of the metal layers MG1 and MG2 and the second field dielectric film 110b, respectively. The first to third gate dielectric films 150a, 150b and 150c may include a high-k dielectric material having a higher dielectric constant than a silicon oxide film. For example, the first to third gate dielectric films 150a, 150b and 150c may include HfO₂, ZrO₂ or Ta₂O₅.

The second gate dielectric film 150b may be spaced apart from the epitaxial layer 145 by the spacer 141 and the third regions 107a and 107b without making contact with the epitaxial layer 145. In addition, the epitaxial layer 145 and the first field dielectric film 110a may also be spaced apart from each other by the third regions 107a and 107b.

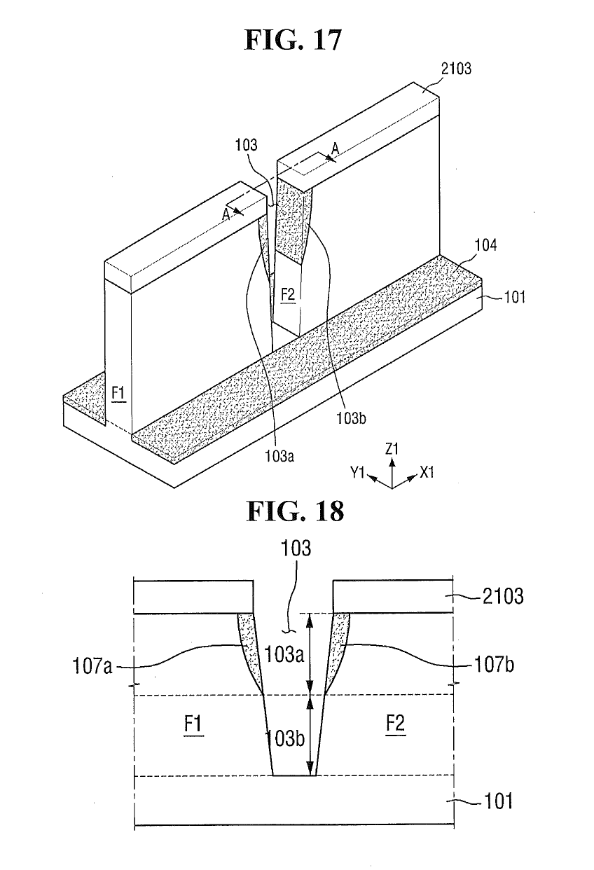

A method for fabricating the semiconductor device according to another embodiment of the present inventive concept will now be described with reference to FIGS. 17 to 20. Repeated descriptions of the methods for fabricating the semiconductor devices according to the present and previous embodiments of the present inventive concept will be omitted and the following description will focus on differences therebetween.

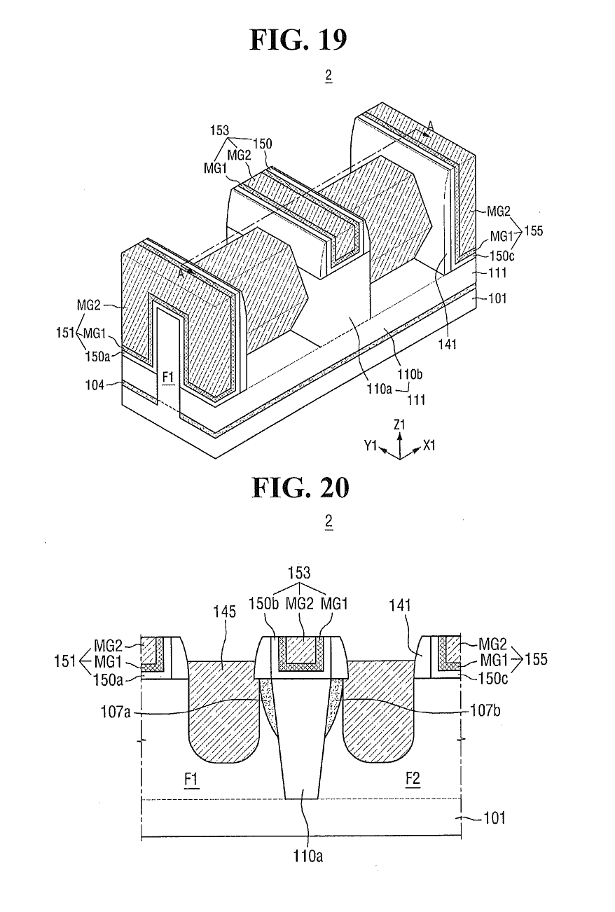

FIGS. 17 to 20 illustrate intermediate process steps of a method for fabricating a semiconductor device according to another embodiment of the present inventive concept. In detail, FIGS. 17 and 19 are perspective views of a method for fabricating a semiconductor device according to another embodiment of the present inventive concept, FIG. 18 is a cross-sectional view taken along the line A-A of FIG. 17 and FIG. 20 is a cross-sectional view taken along the line A-A of FIG. 19.

Up to the process steps illustrated in FIGS. 1 to 5, the method for fabricating a semiconductor device according to another embodiment of the present inventive concept is substantially the same as the method for fabricating a semiconductor device according to an embodiment of the present inventive concept, except for a doped region after performing ion implantation 105.

Referring to FIGS. 17 and 18, impurities are injected into third regions 107a and 107b, that is, a first region 103a of a trench 103 by ion implantation 105, specifically angled ion implantation. In addition, the impurities are doped into a top surface of a substrate 101 without a first mask 2103, thereby forming a doped region 104 on a top surface of the substrate 101. In detail, the top surface of a substrate 101 may be divided into a first surface and a second surface. The first fin F1, the second fin F2 and the trench 103 between the first and second fins F1 and F2 are not positioned on the first surface, while the first fin F1, the second fin F2 and the trench 103 between the first and second fins F1 and F2 are positioned on the second surface. Here, the impurities may be doped into the first surface of the substrate 101, and the first surface is a doped region 104. Even if a portion of the doped region 104 is formed in the substrate 101, the impurities are not doped into other portions of the first and second fins F1 and F2, except for the third regions 107a and 107b, so that performance of transistor may not be affected by the doped region 104.

Next, the process steps of the method for fabricating a semiconductor device according to another embodiment of the present inventive concept are performed in the same manner as shown in FIGS. 8 to 14. The semiconductor device shown in FIGS. 19 and 20 can be fabricated by replacing the first to third dummy gates 131, 133 and 135 with the first to third gate structures 151, 153 and 155.

A doped region 104 may be formed on a first surface of the substrate 101, on which the first fin, the second fin and the first field dielectric film 110a between first fin F1 and the second fin F2 are not positioned, and the doped region 104 may not be formed on a second surface of the substrate 101, on which the first fin F1, the second fin F2 and a trench 103 between the first and second fins F1 and F2 are positioned. Accordingly, the semiconductor device 2 according to another embodiment of the present inventive concept, including the doped region 104, can be fabricated.

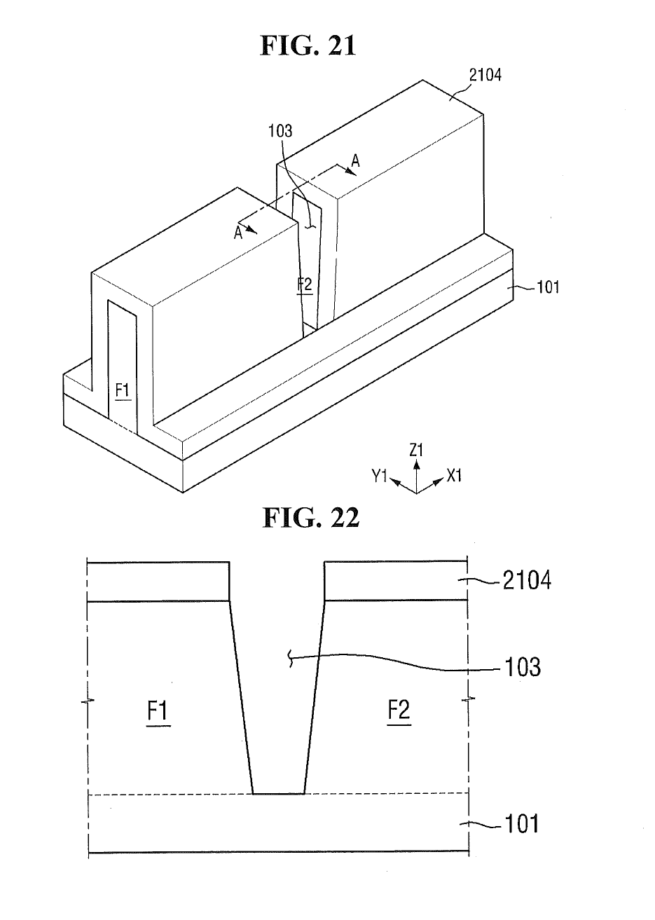

A method for fabricating the semiconductor device according to another embodiment of the present inventive concept will now be described with reference to FIGS. 21 to 24. Repeated descriptions of the methods for fabricating the semiconductor devices according to the present and previous embodiments of the present inventive concept will be omitted and the following description will focus on differences therebetween,

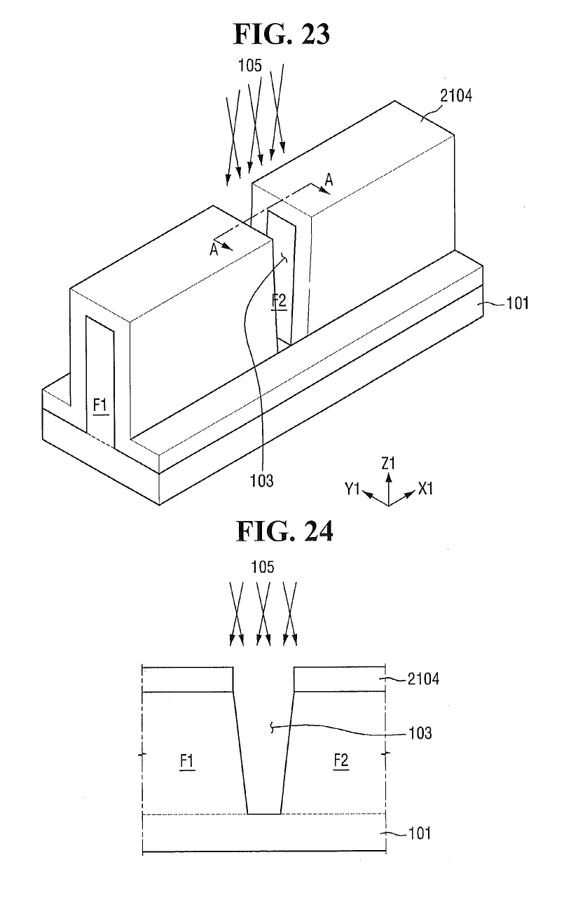

FIGS. 21 to 24 illustrate intermediate process steps of a method for fabricating a semiconductor device according to still another embodiment of the present inventive concept. In detail, FIGS. 21 and 23 are perspective views of a method for fabricating a semiconductor device according to still another embodiment of the present inventive concept, FIG. 22 is a cross-sectional view taken along the line A-A of FIG. 21, and FIG. 24 is a cross-sectional view taken along the line A-A of FIG. 23.

Up to the process steps illustrated in FIGS. 1 to 3, the method for fabricating a semiconductor device according to still another embodiment of the present inventive concept is substantially the same as the method for fabricating a semiconductor device according to an embodiment of the present inventive concept.

Referring to FIGS. 21 and 22, a first mask 2103 is removed and a second mask 2104 is formed on a substrate 101. The second mask 2104 covers a remaining portion of the substrate 101, except for a trench 103. As shown in FIG. 21, the second mask 2104 may be conformally formed along a top surface of the substrate 101 and sidewalls and top surfaces of the first and second fins F1 and F2, but aspects of the present inventive concept are not limited thereto. For example, the second mask 2104 may be formed on the first and second fins F1 and F2 to be spaced apart from the substrate 101 and may not expose the remaining portion except for the trench 103.

Referring to FIGS. 23 and 24, after forming the second mask 2104, ion implantation 105 is performed. The ion implantation 105 may be angled ion implantation. As described above with reference to FIGS. 6 and 7, impurities may be injected into a first region 103a of the trench 103. Next, the second mask 2104 is removed, and the semiconductor device 1 according to the embodiment of the present inventive concept can be fabricated by the same method as shown in FIGS. 8 to 16.

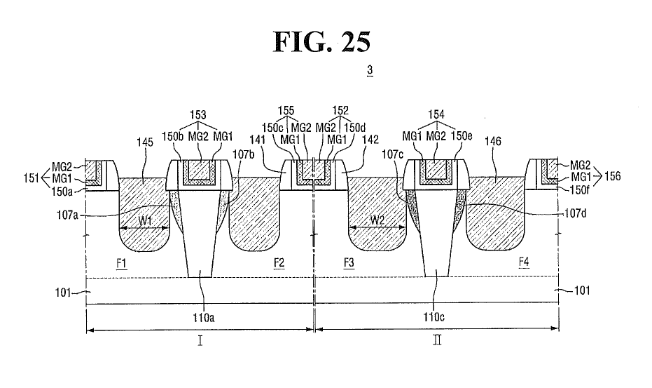

A semiconductor device 3 according to still another embodiment of the present inventive concept will now be described with reference to FIG. 25. Repeated descriptions of the methods for fabricating the semiconductor devices according to the present and previous embodiments of the present inventive concept will be omitted and the following description will focus on differences therebetween.

FIG. 25 is a cross-sectional view of a semiconductor device according to still another embodiment of the present inventive concept.

Referring to FIG. 25, in the semiconductor device 3 according to still another embodiment of the present inventive concept, a substrate 101 may include a first region I and a second region II. Since a transistor formed in the first region I is the same as the semiconductor device 1 according to the embodiment of the present inventive concept, a detailed description thereof will be omitted.

A transistor formed in the second region II is formed using the same material as that formed in the first region I and may be formed in the same manner as that formed in the first region I. In addition, the second region II may be formed at the same with the first region I. Third and fourth fins F3 and F4 may correspond to first and second fins F1 and F2, a third field dielectric film 110c may correspond to a first field dielectric film 110a, a second source/drain 146 may correspond to a first source/drain 145 that is an epitaxial layer, and fourth regions 107c and 107d may correspond to third regions 107a and 107b doped with impurities. In addition, first to third gate structures 151, 153 and 155 may correspond to fourth to sixth gate structures 152, 154 and 156, respectively. Therefore, the first and second normal gate structures 151 and 155 may correspond to the third and fourth normal gate structures 152 and 156, and a first dummy gate structure 153 may correspond to the second dummy gate structure 154. Since a method for fabricating a transistor formed in the second region II is the same as the method for fabricating a transistor formed in the first region I, a detailed description thereof will be omitted.

However, the first region I and the second region II are different from each other in view of the first source/drain 145, the second source/drain 146, the third regions 107a and 107b and the fourth regions 107c and 107d. In detail, the first source/drain 145 of the first region I is larger than the second source/drain 146 of the second region II in size. In other words, a width W1 of the first source/drain 145 in the first and second fins F1 and F2 may be smaller or less than a width W2 of the second source/drain 146 in the third and fourth fins F3 and F4. Therefore, a volume of the first source/drain 145 in the first and second fins F1 and F2 may be smaller than a volume of the second source/drain 146 in the third and fourth fins F3 and F4.

Since the size of the second source/drain 146 is larger or greater than that of the first source/drain 145, the third and fourth fins F3 and F4 of the second region II should be etched more than the first and second fins F1 and F2 of the first region I to form the second source/drain 146. In order to remove the third and fourth fins F3 and F4 of the second region II more than the first and second fins F1 and F2 of the first region I, the etching should be performed on the second region II for a longer time than on the first region I. In addition, more amounts of the third and fourth fins F3 and F4 of the second region II should be etched more rapidly for the same time period than the first and second fins F1 and F2 of the first region I. If the third and fourth fins F3 and F4 are etched more rapidly and for a longer time, sidewalls of the third field dielectric film 110c may be exposed with an increased probability. Therefore, in order to prevent the third field dielectric film 110c from being exposed, that is, in order to prevent the fourth regions 107c and 107d from being etched, larger amounts of impurities should be injected into the fourth regions 107c and 107d. The more the impurities are injected, the less the regions are etched. Therefore, a concentration of impurities doped into the fourth regions 107c and 107d of the second region II is higher than that of impurities doped into the third regions 107a and 107b of the first region I.

Meanwhile, in order to make the first source/drain 145 and the second source/drain 146 have different sizes, a height of the second source/drain 146 may be made to be higher than a height of the first source/drain 145.

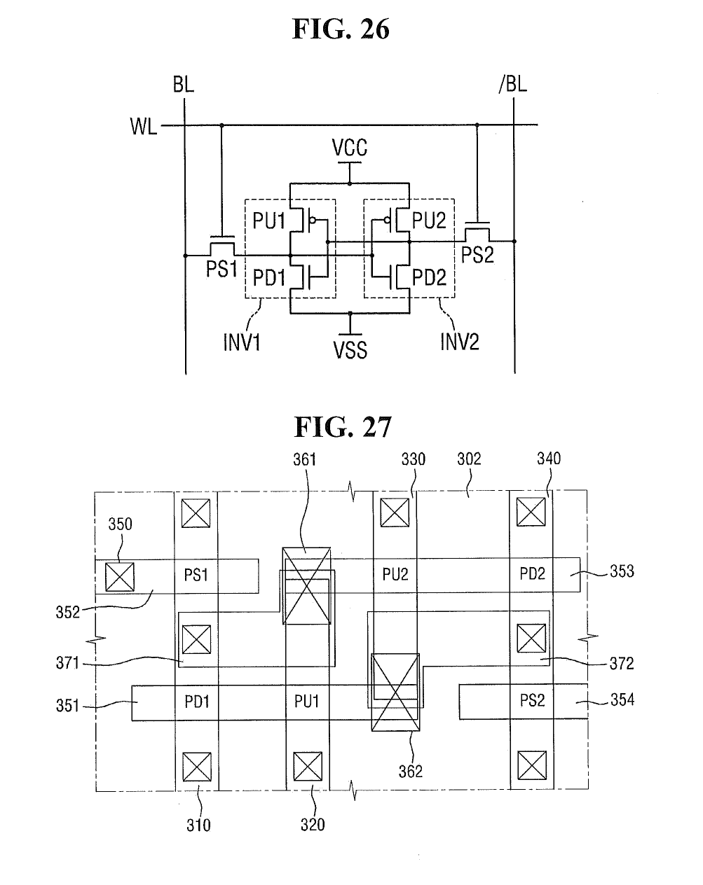

A semiconductor device according to still another embodiment of the present inventive concept will now be described with reference to FIGS. 26 and 27.

FIGS. 26 and 27 are a circuit view and a layout view of a semiconductor device according to still another embodiment of the present inventive concept.

The semiconductor device according to still another embodiment of the present inventive concept can be applied to all devices including general logic devices using fin type transistors, but an SRAM is exemplified in FIGS. 26 and 27.

First, referring to FIG. 26, the semiconductor device according to still another embodiment of the present inventive concept may include a pair of inverters INV1 and INV2 connected in parallel between a power supply node Vcc and a ground node Vss, and a first pass transistor PS1 and a second pass transistor PS2 connected to output nodes of the respective inverters INV1 and INV2. The first pass transistor PS1 and the second pass transistor PS2 may be connected to a bit line BL and a complementary bit line/BL, respectively. Gates of the first pass transistor PSI and the second pass transistor PS2 may be connected to word lines WL.

The first inverter INV1 may include a first pull-up transistor PU1 and a first pull-down transistor PD1 connected in series, and the second inverter INV2 may include a second pull-up transistor PU2 and a second pull-down transistor PD2 connected in series. The first pull-up transistor PU1 and the second pull-up transistor PU2 may be PMOS transistors, and the first pull-down transistor PD1 and the second pull-down transistor PD2 may be NMOS transistors.

In addition, in order to allow the first inverter INV1 and the second inverter INV2 to constitute a latch circuit, an input node of the first inverter INV1 is connected to the output node of the second inverter INV2, and an input node of the second inverter INV2 is connected to the output node of the first inverter INV1.

Referring to FIGS. 26 and 27, a first fin 310, a second fin 320, a third fin 330 and a fourth fin 340, which are spaced apart from one another, are formed to extend lengthwise in a direction (for example, in an up-down direction shown in FIG. 26). The second fin 320 and the third fin 330 may extend in shorter lengths than the first fin 310 and the fourth fin 340.

In addition, the first gate electrode 351, the second gate electrode 352, the third gate electrode 353 and the fourth gate electrode 354 extend lengthwise in the other direction (for example, in a left-right direction shown in FIG. 26) so as to cross the first fin 310 to the fourth fin 340.

In detail, the first gate electrode 351 may completely cross the first fin 310 and the second fin 320 and may partially overlap with a terminal end of the third fin 330. The third gate electrode 353 may completely cross the fourth fin 340 and the third fin 330 and may partially overlap with a terminal end of the second fin 320. The second gate electrode 352 and the fourth gate electrode 354 are formed to cross the first fin 310 and the fourth fin 340, respectively.

As shown, the first pull-up transistor PU1 is defined around a region where the first gate electrode 351 and the second fin 320 cross each other, the first pull-down transistor PD1 is defined around a region where the first gate electrode 351 and the first fin 310 cross each other, and the first pass transistor PS1 is defined around a region where the second gate electrode 352 and the first fin 310 cross each other. The second pull-up transistor PU2 is defined around a region where the third gate electrode 353 and the third fin 330 cross each other, the second pull-down transistor PD2 is defined around a region where the third gate electrode 353 and the fourth fin 340 cross each other, and the second pass transistor PS2 is defined around a region where the fourth gate electrode 354 and the fourth fin 340 cross each other.

Although not shown, recesses may be formed at opposite sides of the regions where the first to fourth gate electrodes 351 to 354 and the first to fourth fins 310, 320, 330 and 340 cross each other, and sources/drains may be formed in the recesses.

In addition, a plurality of contacts 350 may be formed.

A shared contact 361 concurrently connects the second fin 320, the third gate line 353 and an interconnection 371. The shared contact 361 may also concurrently connect the third fin 330, the first gate line 351 and an interconnection 372.

The first pull-up transistor PU1, the second pull-up transistor PU2, the first pull-down transistor PD1 and the second pull-down transistor PD2 may be implemented as fin type transistors, that is, the semiconductor devices 1 to 3, and may have the same configuration as that of one of the aforementioned transistors according to the embodiments of the present inventive concept shown in FIGS. 15, 16, 19, 20 and 25.

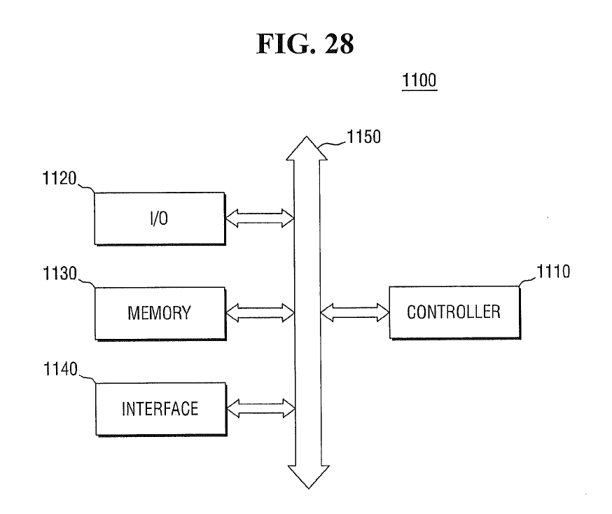

FIG. 28 is a block diagram of an electronic system including semiconductor devices 1 to 3 according to some embodiments of the present inventive concept.

Referring to FIG. 28, the electronic system 1100 may include a controller 1110, an input/output device (I/O) 1120, a memory 1130, an interface 1140 and a bus 1150. The controller 1110, the I/O 1120, the memory 1130, and/or the interface 1140 may be connected to each other through the bus 1150. The bus 1150 corresponds to a path through which data moves.

The controller 1110 may include at least one of a microprocessor, a digital signal processor, a microcontroller, and logic elements capable of functions similar to those of these elements. The I/O 1120 may include a keypad, a keyboard, a display device, and so on. The memory 1130 may store data and/or commands. The interface 1140 may perform functions of transmitting data to a communication network or receiving data from the communication network. The interface 1140 may be wired or wireless. For example, the interface 1140 may include an antenna or a wired/wireless transceiver, and so on. Although not shown, the electronic system 1100 may further include high-speed DRAM and/or SRAM as the operating memory for improving the operation of the controller 1110. The semiconductor devices 1 to 3 according to some embodiments of the present inventive concept may be provided in the memory 1130 or may be provided some components of the controller 1110 or the I/O 1120.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

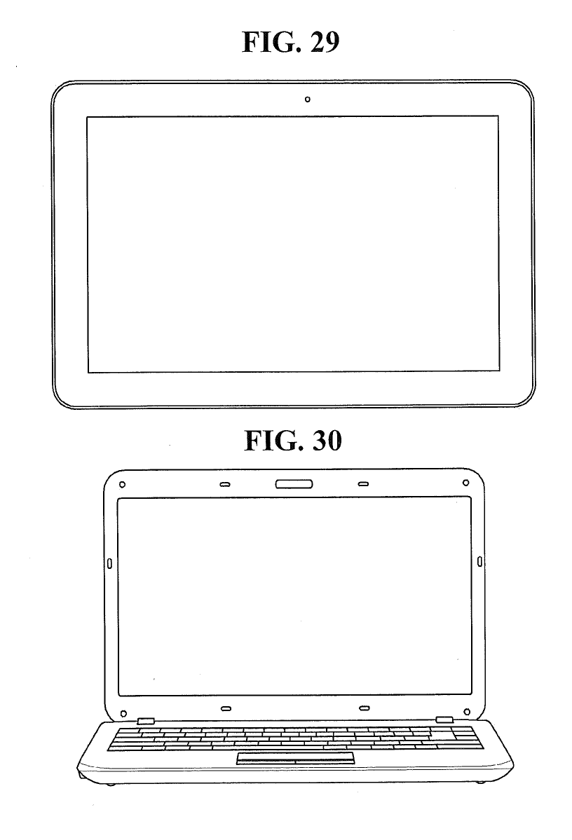

FIGS. 29 and 30 illustrate an exemplary semiconductor system to which semiconductor devices 1 to 3 according to some embodiments of the present inventive concept can be employed. FIG. 29 illustrates an example in which a semiconductor device according to an embodiment of the present inventive concept is applied to a tablet PC, and FIG. 30 illustrates an example in which a semiconductor device according to an embodiment of the present inventive concept is applied to a notebook computer. At least one of the semiconductor devices 1 to 3 according to some embodiments of the present inventive concept can be employed to a tablet PC, a notebook computer, and the like. It is obvious to one skilled in the art that the semiconductor devices according to some embodiments of the present inventive concept may also be applied to other IC devices not illustrated herein.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A method for fabricating a multi-gate transistor device, the method comprising:
forming first and second fins of the multi-gate transistor device shaped to protrude on a substrate and aligned and extending in a first direction and a trench separating the first and second fins from each other in the first direction between the first and second fins;
performing an angled ion implantation of impurities on sidewalls of the trench;
forming a field dielectric film filling the trench;
forming a recess in the first fin not exposing the field dielectric film; and
growing an epitaxial layer in the recess.

2. The method of claim 1, wherein the impurities include at least one of nitrogen (N) and carbon (C).

3. The method of claim 1, wherein the epitaxial layer is a source/drain.

4. The method of claim 1, wherein the sidewalls of the trench include a first region and a second region, the second region is positioned closer to the substrate than the first region, and the performing the ion implantation comprises performing ion implantation on the first region.

5. The method of claim 4, wherein the performing ion implantation comprises not doping impurities into a bottom surface of the trench.

6. The method of claim 1, wherein forming the first and second fins and the trench comprises:
forming the first and second fins on the substrate;
forming a first mask at a portion where the first and second fins are disposed opposite the substrate;
forming the first and second fins and the trench using the first mask as a mask; and
removing the first mask after the performing the ion implantation.

7. The method of claim 1, further comprising, before the performing the ion implantation, forming a second mask on the substrate, the second mask covering a remaining portion except for the trench.

8. The method of claim 1, further comprising, after the forming the field dielectric film, forming a first dummy gate extending on the first fin in a second direction and a second dummy gate extending on the field dielectric film in the second direction, wherein the forming the recess comprises forming the recess between the first dummy gate and the second dummy gate.

9. The method of claim 8, further comprising, after the forming the epitaxial layer, replacing the first and second dummy gates with a gate structure and a dummy gate structure, respectively.

10. A multi-gate transistor device comprising:
first and second fins on a first region of a substrate, aligned and extending in a first direction and spaced apart from each other in the first direction;
a first field dielectric film between the first and second fins;
a first dummy gate structure extending on the first field dielectric film in a second direction and a first gate structure extending on the first fin in the second direction; and
a first source/drain between the first gate structure and the first dummy gate structure,
wherein the first fin includes a third region disposed between the first source/drain and the first field dielectric film and doped with impurities.

11. The multi-gate transistor device of claim 10, wherein a height of the third region is less than a height of the first field dielectric film, and the third region is spaced apart from the substrate.

12. The multi-gate transistor device of claim 10, wherein a top surface of the substrate includes a first surface on which the first fin, the second fin and the first field dielectric film are not positioned, and a second surface on which the first fin, the second fin and the first field dielectric film are positioned, and the first surface is doped with the impurities.

13. The multi-gate transistor device of claim 10, further comprising a spacer disposed on at least one side of the dummy gate structure, wherein a portion of the source/drain contacts a bottom surface of the spacer.

14. The multi-gate transistor device of claim 10, wherein the substrate further includes a second region, the second region includes third and fourth fins shaped to protrude on the second region, aligned and extending in a first direction and spaced apart from each other in the first direction, a second field dielectric film formed between the third and fourth fins, a second dummy gate structure extending on the second field dielectric film in a second direction, a second gate structure extending on the third fin in the second direction, and a second source/drain formed between the second normal gate structure and the second dummy gate structure, wherein the third fin is positioned between the second source/drain and the second field dielectric film and includes a fourth region doped with the impurities, wherein a width of the second source/drain is greater than a width of the first source/drain, and an impurity doping concentration of the fourth region is greater than an impurity doping concentration of the third region.

15. A method for fabricating a multi-gate transistor device, the method comprising:
etching an active region formed on a substrate down to the substrate using a first mask extending in a first direction to form a fin shape;
etching the fin shape down to the substrate to form a trench between a first fin and a second fin aligned with the first fin in the first direction;
performing ion implantation of impurities into the trench at angles not perpendicular to the substrate using the first mask such that impurities are implanted into sidewalls of the first and second fins exposed to the trench and not into the substrate exposed at a bottom of the trench;
forming a field dielectric film to fill the trench;
forming a recess in the first fin not exposing the field dielectric film;
growing a source/drain epitaxial layer in the recess; and
forming a gate on the first fin and a dummy gate on the field dielectric film.

16. The method of claim 15, wherein the forming the recess in the first fin comprises exposing an impurity implanted portion of the first fin, and wherein the growing the source/drain epitaxial layer comprises growing the source/drain epitaxial layer without a void adjacent the field dielectric film.

17. The method of claim 16, wherein each of the sidewalls of the first and second fins exposed to the trench include an upper region contacting the first mask and a lower region between the first region and the substrate, and wherein the performing the ion implantation comprises performing ion implantation into the trench at angles such that ions are implanted into the first regions of the first and second fins and not into the second regions of the first and second fins.

18. The method of claim 17, wherein forming the field dielectric film comprises:
removing the first mask;
forming an insulation layer on the substrate such that the insulation layer fills the trench but exposes top surfaces of the first and second fins;
forming a second mask covering the trench and portions of the first and second fins having impurities implanted into the first regions of the first and second fins;
etching the insulation layer not under the second mask down to the substrate; and
removing the second mask.

19. The method of claim 15, wherein the trench is a first trench, the recess is a first recess and the source/drain epitaxial layer is a first source/drain epitaxial layer, and wherein the method further comprises:
etching the fin shape down to the substrate to form a second trench between a third fin and a fourth fin aligned with the third fin in the first direction;
performing ion implantation of impurities into the second trench at angles not perpendicular to the substrate using the first mask such that impurities are implanted into sidewalls of the third and fourth fins exposed to the second trench and not into the substrate exposed at a bottom of the second trench, wherein a concentration of the impurities in the sidewalls of the third and fourth fins is greater than a concentration of the impurities in the sidewalls of the first and second fins;
forming the field dielectric film to fill the second trench;
forming a second recess in the third fin not exposing the field dielectric film; and
growing a second source/drain epitaxial layer in the second recess.

20. The method of claim 19, wherein a width of the second recess is greater than a width of first recess.
